(19) United States
(12) Patent Application Publication
(10) Pub. No.: US 2007/0040198 A1
(43) Pub. Date: Feb. 22, 2007

(54) Semiconductor device and manufacturing method thereof, and thin film device

(75) Inventor: Osamu Matsuura, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/358,077

(22) Filed: Feb. 22, 2006

(30) Foreign Application Priority Data
Aug. 17, 2005 (JP) 2005-236935

(51) Int. Cl. H01L 29/94

(52) U.S. Cl. 257/296

(57) ABSTRACT

A manufacturing method of a semiconductor device is disclosed. The manufacturing method includes the steps of forming a contact plug in an insulation film so as to be connected to an element on a semiconductor substrate, applying a PLA process to the insulation film in an NH₃ atmosphere, forming a Ti film on the contact plug, nitriding the Ti film to form a TiN film as a part of a lower electrode of a capacitor, and forming a metal film as another part of the lower electrode of the capacitor on the titanium nitride film.

### CROSS-REFERENCE TO RELATED APPLICATIONS

This application is based upon and claims priority of Japanese Patent Application No. 2005-236935, filed in Aug. 17, 2005, the contents being incorporated herein by reference.

### BACKGROUND OF THE INVENTION

1. Field of the Invention

The present invention generally relates to a semiconductor device and a manufacturing method thereof in which a ferroelectric capacitor is formed, and a thin film device which needs excellent orientation.

2. Description of the Related Art

A DRAM (dynamic random access memory) or a SRAM (static RAM) being a volatile memory and a FLASH memory being a non-volatile memory have been used in various fields. On the other hand, as a memory which has both high-speed low-voltage operability of DRAM and non-volatile property of FLASH, FRAM (ferroelectric RAM), MRAM (magnetic RAM), and PRAM (programmable RAM) have potential, and various research and development efforts have been made of these devices. In fact, some of them have been mass-produced.

FRAM is a non-volatile memory making use of hysteresis of a ferroelectric material. A semiconductor device comprising a FRAM has a capacitor structure in which an upper electrode, a ferroelectric layer, and a lower electrode are disposed on a substrate. As a ferroelectric material for the ferroelectric layer, Pb(Zr,Ti)O₃ [PZT] has large spontaneous polarization and has great potential. To form a ferroelectric layer, a CVD (chemical vapor deposition) method is suitable because of forming a dense film.

One of the technological issues in the ferroelectric capacitor is to increase capacity by making its structure fine. For miniaturization of the device structure, several methods are being considered. That is, employing a 1T1C (one transistor and one capacitor) circuit structure in place of a 2T2C (two transistors and two capacitors) circuit structure, employing a stack structure in place of a planar structure, and employing a three-dimensional structure in place of a flat structure.

To change the structure from a planar structure to a stack structure, it is necessary to form a lower electrode right above a transistor via a plug. In order to prevent oxidization of the plug, the lower electrode itself must have an oxygen barrier property. Further, in order that the PZT have large spontaneous polarization, the PZT itself must have excellent orientation and crystal quality. In order to achieve this, the lower electrode positioned under the ferroelectric layer (PZT layer) also must have excellent orientation and crystal quality.

To obtain excellent orientation in the ferroelectric capacitor, it is proposed to perform PLA (plasma annealing) on a silicon substrate in an NH₃ atmosphere prior to forming a lower electrode, and then, to form a Ti film (for example, refer to Patent Document 1). A lower electrode made of Ir and so on is formed on the Ti film. However, the Ti itself becomes TiOx having an insulating property in a high temperature oxygen atmosphere. For this reason, when the Ti film is used on the plug, electric contact between the capacitor and the plug cannot be obtained.

Meanwhile, to prevent oxidization between the lower electrode of the capacitor and the plug, it is proposed to form a cavity by removing the uppermost end of a metal plug filling in a contact hole and to form a conductive film, such as a TiN film, in the cavity by sputtering, thereby forming a plug having a high oxidization preventing effect (for example, refer to Patent Document 2). However, in this method, a plug having a TiN film on the uppermost position comes into contact with an Ir/IrO₂ lower electrode.

Further, as a method for ensuring good electric characteristics of a ferroelectric capacitor, it is proposed to form a contact plug itself using TiN by vapor deposition and to form a lower electrode made of IrO₂ on the contact plug (for example, refer to Patent Document 3).

However, with the above-described conventional methods aiming to prevent the oxidization, crystal orientation of the capacitor is not considered at all.

[Patent Document 1] Japanese Laid-Open Patent Application No. 2004-153031

[Patent Document 2] Japanese Laid-Open Patent Application No. 2001-284548

[Patent Document 3] Japanese Laid-Open Patent Application No. 2000-114482

When a Ti film is formed after the PLA process, the crystal quality becomes good, and the orientation of the ferroelectric material of a capacitor can be well maintained. However, electric contact between the plug and the capacitor cannot be sufficiently obtained due to inferiority in a low oxidization preventing effect.

On the other hand, when a TiN film formed by sputtering or vapor deposition is inserted between a plug and a capacitor, a good oxidization preventing effect is obtained; however, satisfactory crystal quality cannot be obtained.

### SUMMARY OF THE INVENTION

Accordingly, the present invention may provide a semiconductor device with a ferroelectric capacitor whose electric characteristics are excellent by simultaneously providing good crystal quality and a high oxidization preventing effect and a method thereof. Further, in a preferred embodiment of the present invention, there is provided a thin film device that requires excellent orientation.

According to an embodiment of the present invention, instead of forming a titanium nitride (TiN) film directly by sputtering or vapor deposition, a titanium (Ti) film is formed first, and then, the titanium film is nitrided by applying a RTA (rapid thermal annealing) process in a nitrogen-containing atmosphere to form a TiN film. With this method, the crystal quality of the titanium nitride film can be improved, while maintaining the oxygen barrier property.

In addition, by forming a Ti film after PLA (plasma annealing), a TiN film is formed by nitriding the Ti film by applying the PLA process in an atmosphere containing nitrogen. Then a TiN film with more excellent crystal quality can be obtained, as compared with the TiN film obtained by nitriding a Ti film by nitrogen annealing without PLA.

Specifically, according to a first aspect of the present invention, there is provided a semiconductor device. The semiconductor device includes a capacitor having a titanium nitride film as a part of a lower electrode, and the titanium nitride film is a film in which a titanium film formed after applying a PLA process is nitrided.

Preferably, a FWHM (full width half maximum) of the (111) face of the titanium nitride film at a peak in an XRD (X-ray diffraction) pattern formed by a rocking curve method is in a range of 2° to 7°.

More preferably, the FWHM at the peak is in a range of 3° to 5°.

According to a second aspect of the present invention, there is provided a thin film device. The thin film device includes a semiconductor substrate, a titanium nitride film on the semiconductor substrate, and an orientation film on the titanium nitride film. In the thin film device, a FWHM at a peak on the (111) face in an XRD pattern formed by a rocking curve method of the titanium nitride film is in a range of 2° to 7°. More preferably, the FWHM at the peak is in a range of 3° to 5°.

The orientation film includes a metal thin film, a dielectric thin film, a piezoelectric thin film, a conductive nitride film, a conductive oxide film, or a ferroelectric thin film. When the orientation film is a metal thin film such as an Ir film or a Pt film, or a conductive nitride film such as a TiAlN film, the dielectric thin film, the piezoelectric thin film, and/or the ferroelectric thin film can be formed on the orientation film.

According to a third aspect of the present invention, there is provided a manufacturing method of a semiconductor device. The manufacturing method of the semiconductor device includes the steps of forming a contact plug in an insulation film so as to be connected to an element on a semiconductor substrate, applying a PLA process to the insulation film in an NH₃ atmosphere, forming a titanium film on the contact plug, nitriding the titanium film to form a titanium nitride film as a part of a lower electrode of a capacitor, and forming a metal film as another part of the lower electrode of the capacitor on the titanium nitride film.

According to an embodiment of the present invention, when the TiN film obtained by the above method is used as a part of the lower electrode of a ferroelectric capacitor, the electric characteristics of the ferroelectric capacitor can be improved to a great degree.

Other objects and further features of the present invention will be apparent from the following detailed description when read in conjunction with the accompanying drawings.

### BRIEF DESCRIPTION OF THE DRAWINGS

FIG. 1A is a graph showing XRD (X-ray diffraction) patterns of lower electrode films of five types including an embodiment of the present invention;

FIG. 1B is a graph in which a peak part of the graph shown in FIG. 1A is enlarged;

FIG. 2A is a graph showing rocking curves of TiN films being a structural element of the lower electrode film;

FIG. 2B is a graph showing rocking curves of Ir films being a structural element of the lower electrode film;

FIG. 3 is a table showing measured results of FWHMs (full width half maximums) of TiN films and Ir films being the elements of the lower electrode;

FIG. 4A is a diagram showing a first process for forming the semiconductor device according to the embodiment of the present invention;

FIG. 4B is a diagram showing a second process for forming the semiconductor device according to the embodiment of the present invention;

FIG. 4C is a diagram showing a third process for forming the semiconductor device according to the embodiment of the present invention;

FIG. 4D is a diagram showing a fourth process for forming the semiconductor device according to the embodiment of the present invention;

FIG. 4E is a diagram showing a fifth process for forming the semiconductor device according to the embodiment of the present invention;

FIG. 4F is a diagram showing a sixth process for forming the semiconductor device according to the embodiment of the present invention;

FIG. 4G is a diagram showing a seventh process for forming the semiconductor device according to the embodiment of the present invention; and

FIG. 5 is a flowchart showing processes of forming a ferroelectric capacitor in a manufacturing method of the semiconductor device according to the embodiment of the present invention.

### DESCRIPTION OF THE PREFERRED EMBODIMENT

Referring to the drawings, an embodiment of the present invention is explained.

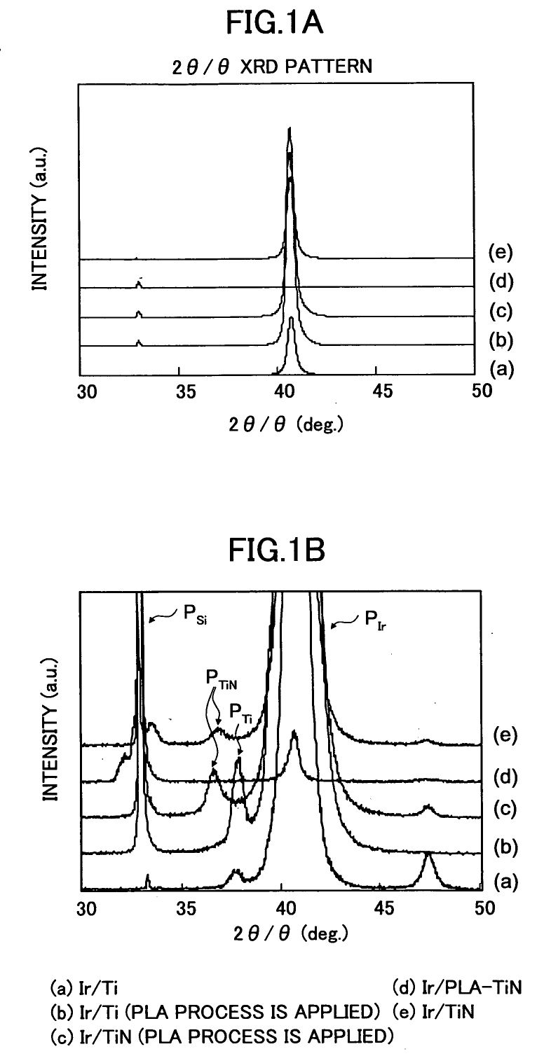

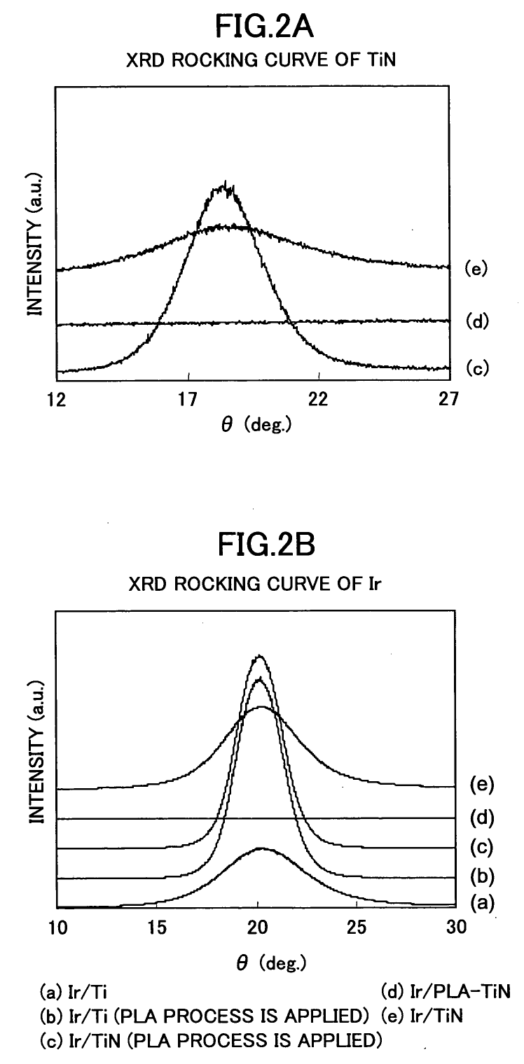

First, referring to FIGS. 1A, 1B, 2A, and 2B, the basic principle of the present invention is explained. In FIGS. 1A through 2B, characteristics of a lower electrode according to the embodiment of the present invention, in comparison with lower electrodes formed by conventional technologies, are shown. FIG. 1A is a graph showing XRD (X-ray diffraction) patterns of lower electrode films of five types including the embodiment of the present invention. FIG. 1B is a graph in which a peak part of the graph shown in FIG. 1A is enlarged. FIG. 2A is a graph showing rocking curves of TiN films formed as the lower electrode film by different methods. FIG. 2B is a graph showing rocking curves of Ir films formed as the lower electrode film.

In FIGS. 1A and 1B, five types of lower electrodes are formed on a silicon substrate and an XRD pattern of each of the films is measured by a 2θ/θ method. The measurement is performed on the (111) face of the lower electrode film (thin film).

In FIGS. 1A and 1B, a pattern (a) is an XRD pattern of an Ir/Ti film in which a Ti film is formed on a silicon substrate without using a PLA process and an Ir film is formed thereon by an existing technology.

In FIGS. 1A and 1B, a pattern (b) is an XRD pattern of an Ir/Ti film in which a Ti film is formed on a silicon substrate after applying the PLA process and an Ir film is formed thereon by a known technology (refer to Patent Document 1).

In FIGS. 1A and 1B, a pattern (c) is an XRD pattern of an Ir/TiN film used as a lower electrode film in the embodiment of the present invention in which a Ti film is formed on a silicon substrate after applying the PLA process and a TiN film is formed by applying an RTA (rapid thermal annealing) process to the Ti film in a nitrogen atmosphere, and an Ir film is formed thereon.

In FIGS. 1A and 1B, a pattern (d) is an XRD pattern of an Ir/PLA-TiN film in which a TiN film is directly formed on a silicon substrate after applying the PLA process by a process such as a sputtering process and a vapor deposition process, and an Ir film is formed thereon. This is a comparison example.

In FIGS. 1A and 1B, a pattern (e) is an XRD pattern of an Ir/TiN film being an lower electrode film in the embodiment of the present invention in which a Ti film is formed on a silicon substrate without applying the PLA process and a TiN film is formed by applying the RTA to the Ti film in a nitrogen atmosphere, and an Ir film is formed thereon.

In FIG. 1B, the patterns (c) and (e) have a peak P_{TiN} of TiN between the silicon peak P_{Si} and the iridium peak P_{Ir}, and the pattern (b) shows a peak P_{Ti} of Ti.

In FIGS. 2A and 2B, the rocking curve on the (111) face of the lower electrode film (thin film) by a θ measuring method is shown. The rocking curve shows the crystal orientation of the thin film (the lower electrode film). In the patterns (a) through (e) of FIGS. 2A and 2B, the same films explained in (a) through (e) of FIGS. 1A and 1B are used. As shown in FIGS. 2A and 2B, in the pattern (d), in which the TiN film is directly formed on the silicon substrate after applying the PLA process by the sputtering process or the vapor deposition process and the Ir film is formed thereon, neither a peak of the TiN film nor a peak of the Ir film on the TiN film are shown, and it is understandable that the crystal orientation is short of satisfactory. That is, even if a directly formed TiN film is used for an element which needs excellent orientation, for example, a ferroelectric capacitor, a piezoelectric element, a liquid crystal element, and so on, this means that the element does not function.

On the other hand, in the pattern (c) according to the embodiment of the present invention in which a Ti film is formed on the silicon substrate after applying the PLA process and a TiN film is formed by applying the RTA process to the Ti film in a nitrogen atmosphere and an Ir film is formed thereon, the TiN film shows a clear peak (refer to FIG. 2A) and also the Ir film formed on the TiN film shows a sharp peak (refer to FIG. 2B). The orientation of a ferroelectric film formed on the above lower electrode is largely improved and a ferroelectric capacitor formed by the ferroelectric film shows an excellent polarization characteristic.

Similarly, in the pattern (e) in the embodiment of the present invention in which a Ti film is formed on a silicon substrate without applying the PLA process and a TiN film is formed by applying the RTA to the Ti film in a nitrogen atmosphere and an Ir film is formed thereon, the TiN film shows a gentle peak (refer to FIG. 2A). However, when the TiN film in the pattern (e) is compared with the TiN film directly formed by a sputtering process in the pattern (d), the TiN film and the Ir film thereon in the pattern (e) show good crystal quality (refer to FIGS. 2A and 2B).

As shown in FIG. 2B, in the pattern (b) by an existing technology in which a Ti film is formed on a silicon substrate after applying the PLA process and an Ir film is formed thereon, the Ir film shows an excellent peak, with this, the Ir film shows excellent crystal quality as a lower electrode. However, as described above, the Ti film is easily oxidized and does not function as an oxygen barrier film.

When the patterns (c) and (e) in the embodiment of the present invention are compared, as shown in FIG. 1B, in the TiN film obtained by nitriding the Ti film deposited without applying the PLA process (pattern (e)), the peak position of the XRD is shifted from that of the pattern (c) and the peak (P_{TiN}) of the pattern (e) is duller than that of the pattern (c). In the XRD pattern, since the peak position is different depending on a lattice constant, in the TiN film nitrided without applying the PLA process (pattern (e)), the lattice constant deviates from the original TiN. That is, the TiN film is not completely nitrided. In other words, it is understandable that the PLA process before forming the Ti film reinforces nitriding Ti.

Both of the patterns (c) and (e) of the lower electrode in the embodiment of the present invention have excellent crystal quality and an oxygen barrier property. However, the pattern (c) having the PLA process applied has a more excellent crystal quality (orientation).

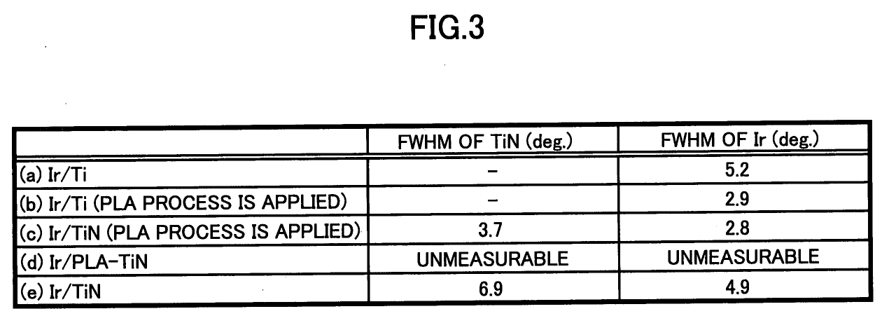

FIG. 3 is a table showing measured results of FWHMs (full width half maximums) of the peaks of the above five patterns (a) through (e) shown in FIGS. 1A through 2B. In FIG. 3, the FWHM of the Ir film and the FWHM of the TiN film being elements of the lower electrode are shown.

In the TiN film directly formed by a sputtering process and so on (pattern (d)), the peak itself does not exist and the FWHM cannot be measured.

In the pattern (a) in which only an Ir film is formed on a Ti film by an existing technology, the FWHM of the Ir film exceeds 5°, and contribution to improving the orientation of a ferroelectric material is low. In addition, the Ti film has a low oxygen barrier property.

In the pattern (b) in which a Ti film is formed after the PLA process and an Ir film is formed thereon by an existing technology, the FWHM of the Ir film on the (111) face is 2.9° being excellent. However, similar to the pattern (a), the Ti film has a low oxygen barrier property.

In the pattern (c) in the embodiment of the present invention, in which a Ti film on the (111) face is formed after the PLA process and a TiN film is formed by applying an RTA process to the Ti film in a nitrogen atmosphere and an Ir film is formed thereon, the FWHM of the Ir film on the (111) face is 2.8°, and the FWHM of the TiN film on the (111) face is 3.7°. Therefore, these show excellent crystal quality. The orientation of a ferroelectric film formed on the above lower electrode film is improved and a capacitor is able to have an excellent polarization characteristic. The FWHM of the TiN film can be made as small as approximate 2° being tuned by a PLA process.

In the pattern (e) in the embodiment of the present invention, in which a Ti film is formed on a silicon substrate without applying the PLA process and a TiN film is formed by applying the RTA to the Ti film in a nitrogen atmosphere and an Ir film is formed thereon, the FWHM of the Ir film on the (111) face is 4.9°, and the FWHM of the TiN film on the (111) face is 6.9°.

When a TiN film, whose FWHM of the XRD is 2° to 7°, preferably, 3° to 5°, is used for a part of the lower electrode, both the oxygen barrier property and the crystal quality can be obtained. In this case, the FWHM of the XRD of the Ir film on the TiN film is 2° to 5°, preferably, 2° to 3°.

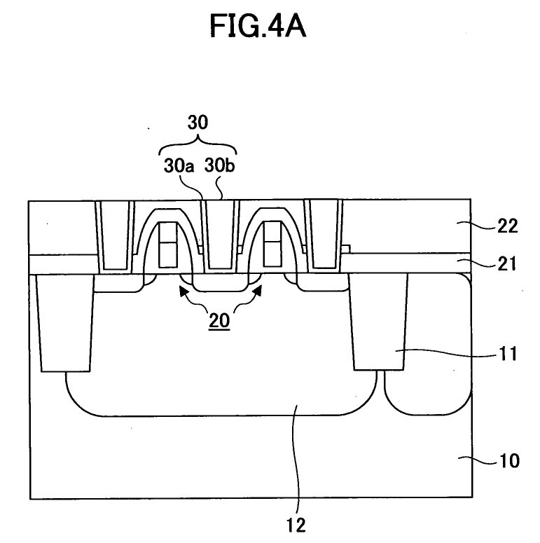

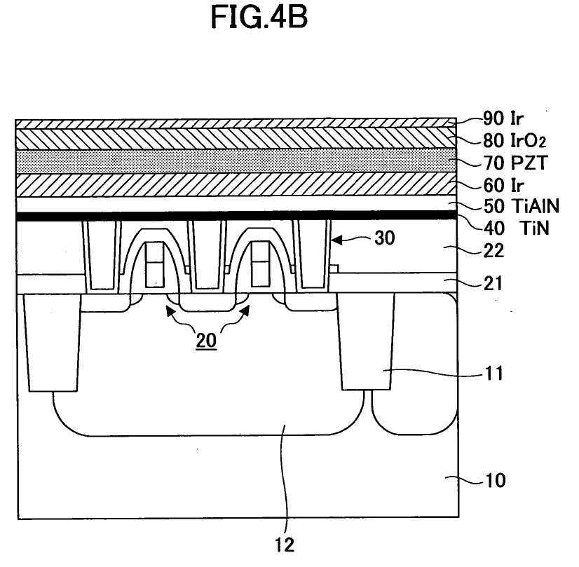

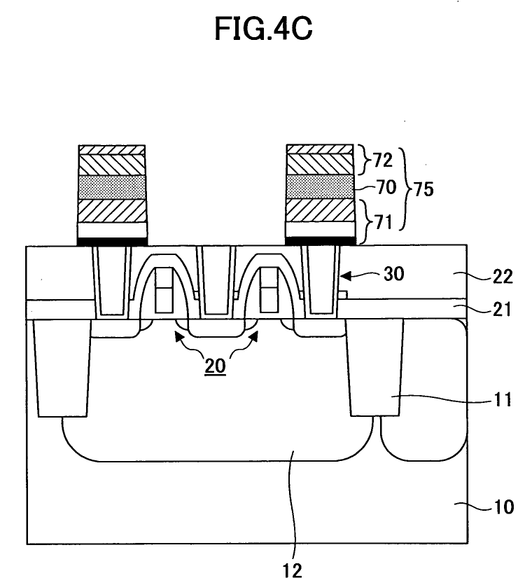

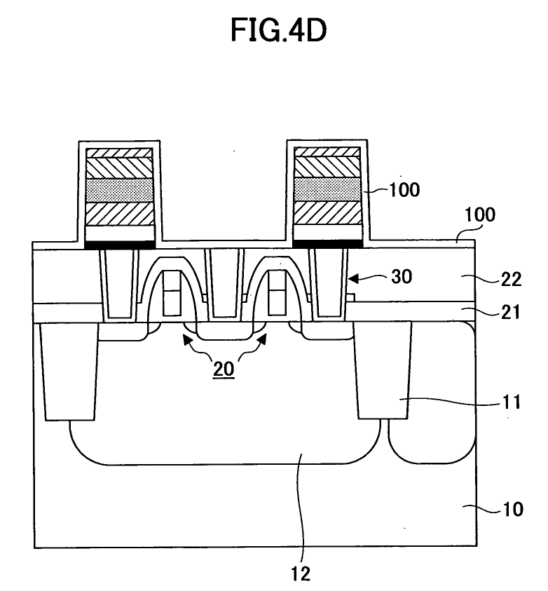

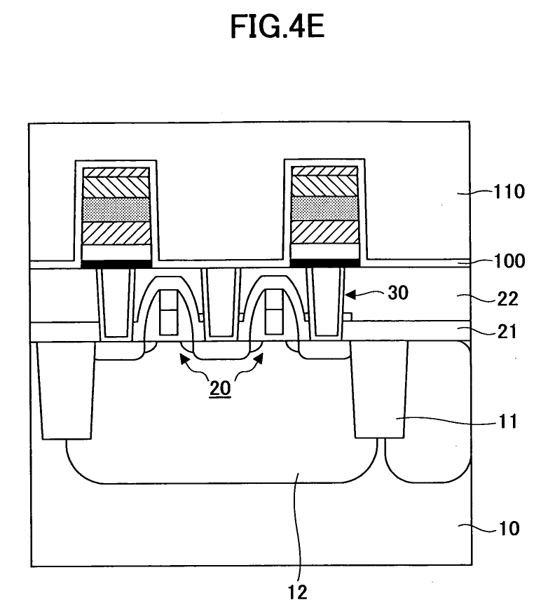

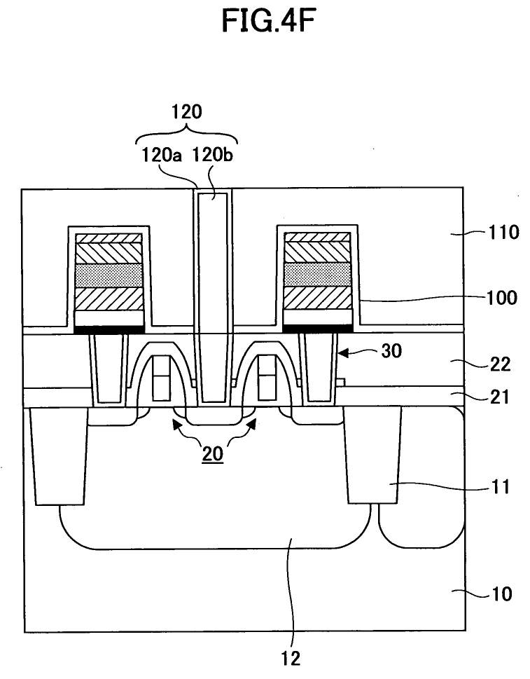

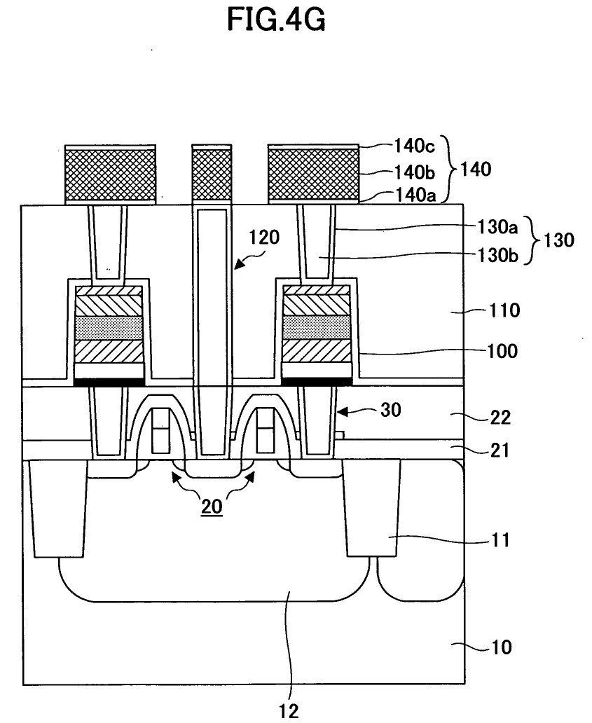

FIGS. 4A through 4G are diagrams showing processes for manufacturing a semiconductor device in which the above TiN film is used for a part of a lower electrode of a capacitor.

As shown in FIG. 4A, first, MOS transistors 20 are formed in a well region 12 isolated by isolation regions 11 on a substrate 10 by an existing method. A cover insulating film 21 (for example, SiON film) for protecting the MOS transistors 20 is formed, a first dielectric inter layer 22 is deposited and a contact plug 30 reaching an impurity diffusion region (source and drain) of the MOS transistors 20 is formed. In forming the contact plug 30, for example, a TiN/Ti glue layer 30a is formed in a contact hole (not shown) opened in the first dielectric inter layer 22 by sputtering, a tungsten (W) layer 30b is deposited by a CVD (chemical vapor deposition) method, and after this, a CMP (chemical mechanical polishing) process is applied and the face is flattened.

Next, as shown in FIG. 4B, lower electrode films 40, 50, and 60, a ferroelectric film 70, and upper electrode films 80 and 90 are deposited on the entire face in this order. In the embodiment, thin films of the lower electrodes are a TiN film 40, a TiAlN film 50, and an Ir film 60. In more detail, in order to make the orientation high, a Ti film whose thickness is 20 nm is formed, and the TiN film 40 is formed by applying an RTA process to the TiN film in an N₂ atmosphere (flow rate is 10 slm) at 650° C. for two minutes. That is, the Ti film is nitrided and the TiN film 40 is formed.

Preferably, before forming the Ti film, a PLA process is applied in an NH₃ atmosphere. The PLA process is performed under the following conditions: for example, the substrate temperature is 400° C., the power of the high frequency power source of 13.56 MHz to be supplied to the substrate is 100 W, the power of the high frequency power source of 350 kHz to be supplied to the plasma generating region is 55 W, and the processing time is 60 seconds. Next, the TiAlN film 50 being an oxygen barrier film whose thickness is 100 nm is formed, and the Ir film 60 being an electrode film whose thickness is 100 nm is formed by sputtering. Further, a PZT film being a first layer whose thickness is 5 nm is deposited by a MOCVD (metal organic chemical vapor deposition) method, and a Pb(Zr,Ti)O₃[PZT] film whose thickness is 115 nm is sequentially formed on the first layer; with this, the ferroelectric film 70 is formed. At this time, the substrate temperature is 620° C. and the pressure is 666 Pa (5 Torr). In addition, on the ferroelectric film 70, an IrO₂ film 80 whose thickness is 150 nm being a part of an upper electrode film for a ferroelectric capacitor is formed by sputtering, and further, an Ir film 90 (a part of an upper electrode film) whose thickness is 50 nm is formed on the IrO₂ film 80. After this, in order to recover from damage to the ferroelectric film 70 caused by forming the upper electrode films 80 and 90, a recovery annealing process is applied. In the embodiment, a furnace annealing process is applied in an annealing furnace at 550° C. for 60 minutes in an O₂ atmosphere.

Next, as shown in FIG. 4C, a ferroelectric capacitor 75 having a stack structure which is formed by an upper electrode 72 (formed by the upper electrode films 90 and 80), the ferroelectric film 70, and a lower electrode 71 (formed by the lower electrode films 60, 50, and 40) is formed. In more detail, a predetermined hard mask (not shown) is formed by a photolithography method, and regions of the upper electrode films 90 and 80, the ferroelectric film 70, and the lower electrode films 60, 50, and 40 where the hard mask does not cover are sequentially removed by an etching process.

Next, as shown in FIG. 4D, an alumina protection film 100 is deposited, and furnace annealing is applied at 550° C. in an O₂ atmosphere for 60 minutes.

Next, as shown in FIG. 4E, a second dielectric inter layer 110 is formed and the face of the second dielectric inter layer 110 is flattened by a CMP process. In this case, the second dielectric inter layer 110 is an oxide film formed by using a HDP (high density plasma) instrument, and the thickness from the upper face of the Ir film 90 being a part of the upper electrode of the ferroelectric capacitor 75 to the flattened face is 300 nm.

Next, as shown in FIG. 4F, a contact hole (not shown) reaching the contact plug 30 is formed by patterning and etching, and a TiN film 120a being a barrier metal or a glue layer and a W (tungsten) film 120b being a contact metal are formed, and the face is flattened by a CMP process. With this, a contact plug 120 is formed.

Next, as shown in FIG. 4G, a contact hole (not shown) connecting to the upper electrode 72 of the ferroelectric capacitor 75 is formed, and a TiN film 130a being a barrier metal and a W (tungsten) film 130b being a contact metal are formed in the contact hole, and the faces of the TiN film 130a and the W film 130b are flattened by a CMP process. With this, a contact plug 130 is formed. Further, a first layer metal wiring 140 is formed by TiN/Al/TiN films. The thickness of each film is as follows: for example, the thickness of a TiN film 140a is 70 nm, the thickness of an Al film 140b is 360 nm, and the thickness of a TiN film 140c is 50 nm. After forming the first layer metal wiring 140, an exposure process and an etching process are applied, and a multi layer wiring forming process is performed by forming a third dielectric inter layer (not shown).

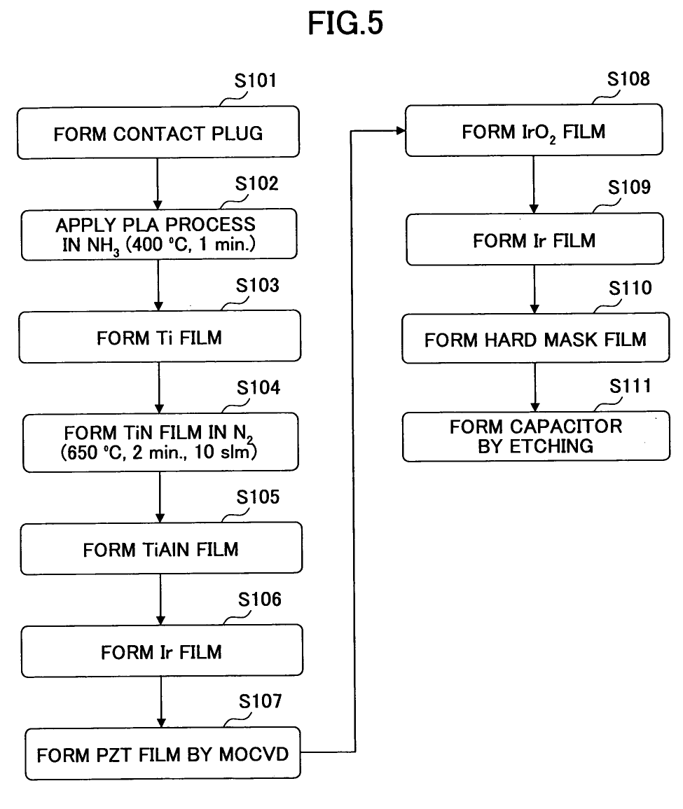

FIG. 5 is a flowchart showing processes of forming a ferroelectric capacitor in a manufacturing method of a semiconductor device according to the embodiment of the present invention.

Referring to the flowchart shown in FIG. 5, the processes are explained.

First, a contact plug 30 connecting to an impurity diffusion region of a MOS transistor 20 is formed (step S101). Next, a PLA process is applied in an NH₃ atmosphere at 400° C. for one minute (step S102). A Ti film is formed (step S103). After this, a TiN film 40 is formed by applying an RTA process to the TiN film in an N₂ atmosphere (10 slm) at 650° C. for two minutes (step S104). A TiAlN film 50 is formed (step S105), and an Ir film 60 is formed (step S106). Further, a PZT film being a ferroelectric film is formed by a MOCVD method (step S107), and an IrO₂ film 80 and an Ir film 90 being elements of an upper electrode are sequentially formed (steps S108 and S109).

Next, a hard mask is formed by stacking, for example, a TiN film and a TEOS (tetra ethyl ortho silicate) film, and patterning with a predetermined pattern (step S110). A ferroelectric capacitor 75 having a predetermined shape is formed by etching the Ir film 90, the IrO₂ film 80, the ferroelectric film 70, the Ir film 60, the TiAlN film 50, and the TiN film 40 with the use of the hard mask (step S111).

In the above embodiment, aspects of the present invention are explained. However, the present invention in not limited to the embodiment. For example, the present invention can be applied to a stack structure or a planar structure in which a material such as Pt is used as the lower electrode. In the embodiment of the present invention, when the ferroelectric film is formed, a sputtering method and a MOCVD method are used. However, another film forming method, such as a spin-on method, and a sol-gel method can be used as the ferroelectric film forming method. Further, as the ferroelectric material, other materials can be used. In addition, various variations and modifications may be made without departing from the scope of the present invention.

Further, in the TiN film in the embodiment of the present invention, since the TiN itself highly orients the (111) face, when a capacitor is formed by using a material utilizing the orientation of the TiN film, the TiN film can be used in various capacitor structures. In addition, the TiN film can be used as a conductive film in various devices which need the orientation and the oxygen barrier property, not only in a capacitor in a FRAM.

The TiN film in the embodiment of the present invention can be used in other thin film devices, for example, a piezoelectric device and a liquid crystal device which needs the orientation. In the above thin film devices, an orientation film is formed on a TiN film whose FWHM at the peak on the (111) face of the XRD by the rocking curve method is in a range of 2° to 7°, preferably, 3° to 5°.

The orientation film is, for example, a metal thin film made of Ir, Pt, and so on, a conductive nitride film such as a TiAlN film, a conductive oxide film, a dielectric thin film, a piezoelectric thin film, and a ferroelectric thin film. When the orientation film is an Ir film, a Pt film, or a TiAlN film, a dielectric thin film, a piezoelectric thin film, and a ferroelectric thin film can be further formed on the orientation film.

In any one of the above cases, by combining the PLA process with nitriding Ti, a TiN film having high orientation and an oxygen barrier property is formed, and the orientation of the orientation film is improved due to the high orientation of the TiN film.

What is claimed is:

1. A semiconductor device, comprising:
a capacitor having a titanium nitride film as a part of a lower electrode, wherein:
the titanium nitride film is a film in which a titanium film formed after applying a PLA (plasma annealing) process is nitrided.

2. A semiconductor device, comprising:
a capacitor having a titanium nitride film as a part of a lower electrode, wherein:
a FWHM (full width half maximum) of the (111) face of the titanium nitride film at a peak in an XRD (X-ray diffraction) pattern formed by a rocking curve method is in a range of 2° to 7°.

3. The semiconductor device as claimed in claim 2, wherein:
the FWHM at the peak is in a range of 3° to 5°.

4. The semiconductor device as claimed in claim 2, further comprising:
a metal film on the titanium nitride film as a part of the lower electrode, wherein:
a FWHM of the (111) face of the metal film at a peak in an XRD pattern formed by a rocking curve method is in a range of 2° to 5°.

5. The semiconductor device as claimed in claim 3, further comprising:
a metal film on the titanium nitride film as a part of the lower electrode, wherein:
a FWHM of the (111) face of the metal film at a peak in an XRD pattern formed by a rocking curve method is in a range of 2° to 3°.

6. The semiconductor device as claimed in claim 4, further comprising:
an oxygen barrier film between the titanium nitride film and the metal film.

7. The semiconductor device as claimed in claim 5, further comprising:
an oxygen barrier film between the titanium nitride film and the metal film.

8. The semiconductor device as claimed in claim 4, further comprising:
a ferroelectric film on the lower electrode.

9. The semiconductor device as claimed in claim 5, further comprising:
a ferroelectric film on the lower electrode.

10. A thin film device, comprising:
a semiconductor substrate;
a titanium nitride film on the semiconductor substrate; and
an orientation film on the titanium nitride film; wherein:
a FWHM of the (111) face of the titanium nitride film at a peak in an XRD pattern formed by a rocking curve method is in a range of 2° to 7°.

11. The thin film device as claimed in claim 10, wherein:
the FWHM at the peak is in a range of 3° to 5°.

12. The thin film device as claimed in claim 10, wherein:
the orientation film includes an Ir film, a Pt film, and a TiAlN film.

13. The thin film device as claimed in claim 11, wherein:
the orientation film includes an Ir film, a Pt film, and a TiAlN film.

14. The thin film device as claimed in claim 10, further comprising:
a dielectric thin film, a piezoelectric thin film, and/or a ferroelectric thin film formed on the orientation film.

15. The thin film device as claimed in claim 11, further comprising:
a dielectric thin film, a piezoelectric thin film, and/or a ferroelectric thin film formed on the orientation film.

16. A manufacturing method of a semiconductor device, comprising the steps of:
forming a contact plug in an insulation film so as to be connected to an element on a semiconductor substrate;
applying a PLA process to the insulation film in an NH₃ atmosphere;
forming a titanium film on the contact plug;
nitriding the titanium film to form a titanium nitride film as a part of a lower electrode of a capacitor; and
forming a metal film as another part of the lower electrode of the capacitor on the titanium nitride film.

17. The manufacturing method of the semiconductor device as claimed in claim 16, wherein:
the nitriding step includes annealing the titanium film in the atmosphere containing nitrogen at 650° C. of semiconductor substrate temperature for two minutes.

18. The manufacturing method of the semiconductor device as claimed in claim 16, further comprising the step of:
forming an oxygen barrier film between the titanium nitride film and the metal film.

19. The manufacturing method of the semiconductor device as claimed in claim 16, further comprising the step of:
forming a ferroelectric capacitor by sequentially forming a ferroelectric film and an upper electrode film on the metal film.
